(19) United States
(12) Patent Application Publication
(10) Pub. No.: US 2008/0160459 A1
(43) Pub. Date: Jul. 3, 2008

(54) METHOD OF FORMING A PATTERN

(76) Inventor: Benjamin Szu-Min Lin, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/616,882

(22) Filed: Dec. 28, 2006

(51) Int. Cl. G03F 7/26

(52) U.S. Cl. 430/323; 430/296

(57) ABSTRACT

A method of forming a pattern comprising steps as follow. A substrate comprising a layer to be etched is provided. A first resist layer is formed on the substrate. The top of the first resist layer is patterned. A second resist layer is formed on the first resist layer being patterned. A portion of the second resist layer is removed. The first resist layer, the second resist layer, and the layer to be etched are etched. A fine pattern can be obtained using the method of the present invention, while the resist layer used is not too thin. Thus, the bad adhesion of the resist layer to the substrate and the less etch resistance of the resist layer for protecting underlying layers will not occur.

### BACKGROUND OF THE INVENTION

1. Field of the Invention

The invention relates to a method of forming a pattern, and in particular, to a method of forming a pattern, for use in the fine patterning step of the method of fabricating a semiconductor device and so forth.

2. Description of the Prior Art

In circuit making processes, a lithographic process has not only been a mandatory technique but also played an important role in limiting feature size. Only by a lithographic process can a wafer producer precisely and clearly transfer a circuit pattern onto a semiconductor wafer. In a lithographic process, a designed pattern, such as a circuit pattern or a doping pattern, is created on one or several photo masks, then the pattern on the mask is transferred by light exposure, with a stepper and scanner, onto a photoresist layer on a semiconductor wafer.

A conventional projection lithography system projects a pattern of radiation onto substrate. The term “substrate” is used herein to refer to a structure upon which a photoresist mask is formed, and is not limited to any particular material or structure. The substrate typically comprises a semiconductor wafer and may also comprise additional material layers, devices, and structures. The projection lithography system typically includes a radiation source, a condenser lens assembly, a reticle, an objective lens assembly, and a stage. The stage supports the substrate and may move the substrate with respect to the lens assembly. Conventional projection lithography systems may further include mirrors, beam splitters, and other components arranged according to other designs. Projection lithography systems may include a lithographic camera or stepper unit.

It is an important issue for solving resolution of the lithographic process due to the device sizes of the semiconductor industry are being reduced. Conventionally, short wavelengths of light, such as ultra-violet light, vacuum ultra-violet (VUV) light, deep ultra violet light, x-ray radiation, and e-beam radiation are used to expose a photoresist layer on the semiconductor wafer. Short wavelengths of light are desirable as the shorter the wavelength, the higher the possible resolution of the pattern, and the resolution of the pattern will be the miniaturization limit of the fabricated IC device. However, when using the short wavelengths of light to increase the resolution of the pattern, the photoresist layer is required to be a thin photoresist layer to match up with the exposure of the short wavelengths of light, but when the photoresist layer is too thin, the photoresist layer will be damaged and unable to protect the underlying layer from being etched in the sequential etching process, and result in a bad process performance.

U.S. Pat. No. 6,689,541 discloses a process for forming a photoresist mask to obtain a narrower line width. As shown in FIG. 1, the process includes applying a photoresist layer 26 to a substrate, and the substrate may include a source/drain diffusion layer 20, a gate insulation layer 22, and a gate layer 24; forming a silyated area 28 in the photoresist layer 26, transforming the silyated area 28 to an oxide cap layer 29 via oxygen plasma etch and remove a portion of the photoresist layer 26 that is not covered by the oxide cap layer 29 at the same time. Performing an etch process again for etching side walls of the photoresist layer 26 to make the line width of the photoresist layer 26 narrower, as shown in FIG. 2. At last, the oxide cap layer 29 is removed to leave the photoresist mask on the substrate.

However, there is still a need for a method of forming a pattern with greater resolution.

### SUMMARY OF THE INVENTION

An objective of the present invention is to provide a method of forming a pattern. The method can form a fine pattern, while the resist layer used is not too thin, and therefore the bad adhesion of the resist layer to the substrate and the less etch resistance of the resist layer for protecting underlying layers will not occur.

An embodiment of the claimed invention provides a method of forming a pattern, comprising steps as follows. A substrate comprising a layer to be etched is provided. A first resist layer is formed on the substrate. A top of the first resist layer is patterned. A second resist layer is formed on the patterned first resist layer. A portion of the second resist layer is removed. The second resist layer, the first resist layer, and the layer to be etched are etched.

Another embodiment of the claimed invention provides a method of forming a pattern comprising steps as follows. A substrate comprising a layer to be etched is provided. A first resist layer is formed on the substrate. A top of the first resist layer is patterned. A second resist layer is formed on the patterned first resist layer and covering the patterned first resist layer. A portion of the second resist layer is removed to expose a portion of the first resist layer. The exposed portion of the first resist layer and the layer to be etched under the exposed portion of the first resist layer are etched.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 and 2 show a conventional method of forming a mask.

FIGS. 3-9 show a method of forming a pattern according to the present invention.

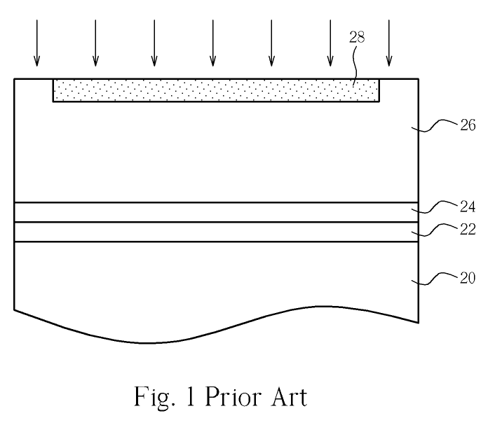

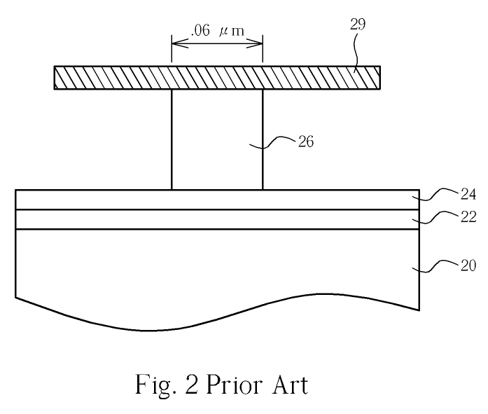

### DETAILED DESCRIPTION

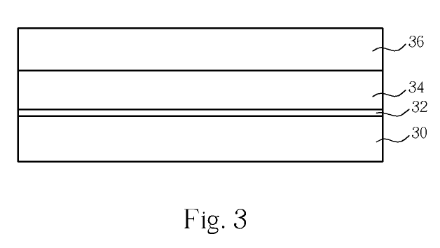

Please refer to FIG. 3 to FIG. 9 showing a schematic cross-sectional view of an embodiment of the method of forming a pattern according to the present invention, wherein like number numerals designate similar or the same parts, regions or elements. It is to be understood that the drawings are not drawn to scale and are used only for illustration purposes.

At first, a substrate is provided, and the substrate may include an insulation layer, a conductive layer, or other layer to form a pattern thereon such as silicon, aluminum, indium tin oxide (ITO), molybdenum, silicon dioxide, doped silicon dioxide, silicon nitride, tantalum, copper, polysilicon, ceramic, aluminum/copper mixture, and various polymer resins, etc., but not limited thereto. The substrate has a layer to be etched. As shown in FIG. 3, in this embodiment, the substrate includes a silicon base 30, a gate dielectric layer 32 and a polysilicon layer 34 on the silicon base 30 as layers to be etched, and a first resist layer 36 is formed on the polysilicon layer 34. The first resist layer may include conventional photoresist materials such as positive photoresist of phenol-formaldehyde polymer, or negative photoresist of isoprene polymer. The resist layer is formed by a method such as a dipping, spraying, rotation, and spin coating, and soft bake may be further included.

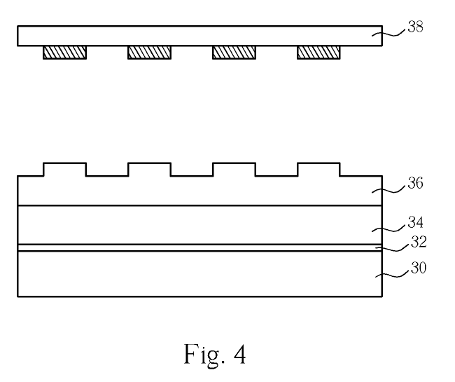

Next, the top of the first resist layer 36 is patterned, but not the whole resist layer is patterned. The top of the first resist layer is patterned using an imprint method, litho-etch method, or electron beam lithography, etc. Please refer to FIG. 4 showing an embodiment of the present invention. The litho-etch method is used to pattern the top of the first resist layer 36, i.e. light (including radiation) is irradiated on the first resist layer 36 through the mask 38. When the positive photoresist is used, the irradiated photoresist will be removed during development, and the un-irradiated photoresist will remain to become the pattern. When the negative photoresist is used, the irradiated photoresist will remain to become the pattern, and the un-irradiated photoresist will be removed during development. The resolution can be increased by irradiation with a light having a short wavelength. In the present invention, the resist layer with a thin thickness is not used intentionally to match up with the short wavelengths of light because not the entire thickness of the photoresist is exposed during exposure, but only the top of the resist layer is exposed. Therefore, the thickness of the resist layer is not required to be thin intentionally, but may be thicker than the exposure depth. In this way, the problems resulted by the over-thin resist layer can be resolved, and the optimal resolution for the pattern can be obtained easily according to the chosen wavelengths of light. Furthermore, although the thickness of the pattern can be thin, the resist layer has a certain total thickness itself in the present invention, and therefore, the resist layer can maintain good adhesion properties with the underlying layers during performing exposure and follow-up removing.

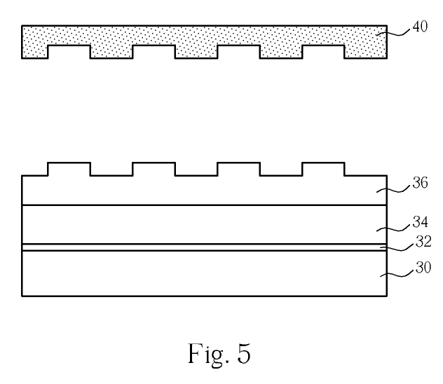

Or, the top of the first resist layer also can be patterned using an imprint method. Please refer to FIG. 5 showing another embodiment of the present invention. An imprint mask 40 having a reverse pattern compared with desired pattern on the top is used. In this way, using the imprint mask 40 to press the first resist layer 36 can obtain a desired pattern on the top. At this time, the resist layer should be the material suitable for pressing, and not necessarily photoresist materials. The patterned resist layer obtained by the imprint method might have a thicker thickness than the patterned resist layer obtained by the litho-etch method, but the patterned resist layer obtained by the imprint method is not required to accommodate itself to the resolution obtained by the wavelengths of light used in the photoresist exposure.

Or, in the other one embodiment of the present invention, the electron beam lithography can be used (not shown) to directly write the pattern on the top of the first resist layer to form the pattern on the top. In the electron beam lithography, the electron beam is generated by the electron gun and accelerated to have energy of 10 to 50 keV (the electron of 10 keV has a wavelength of 0.012 nm). The electron beam is focused to become an electron beam with a diameter of 0.01 to 0.1 micrometers by using focusing lens, and an electron beam black plate and a bias angle coil are controlled by a computer to scan the focused electron beam onto the substrate to accomplish exposure of various patterns. A fine pattern can be obtained using the electron beam lithography. For example, the line having a width of 0.05 micrometers can be directly written on the resist layer of the chip. That is, the resist is exposed directly by the electron beam without using a mask. The resist material used is suitable for the electron beam exposure. Generally, the exposed area to the electron beam is removed, and the unexposed area is the pattern.

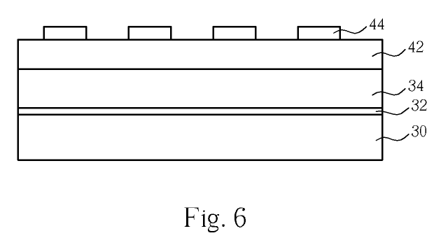

The first resist layer may be a single layer structure or a multi-layer structure. For example, a multi-layer structure is shown in FIG. 6. The first resist layer is composed of a resist material layer 42 and a resist material layer 44. Although in FIG. 6 it shows that a portion of the overlying resist material layer 44 is removed to expose the underlying resist material layer 42, it is not limited thereto. The resist material layer 44 and the resist material layer 42 can be stacked, and only the top of the resist material layer 44 is patterned; or, the resist material layer 44 and the resist material layer 42 can be stacked, and the pattern on the top is formed of the resist material layer 44 and the resist material layer 42 together. The resist material layer 44 and the resist material layer 42 may further be multi-layer structures.

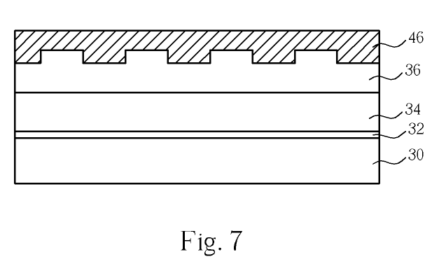

Next, as shown in FIG. 7, a second resist layer 46 is formed on the patterned first resist layer 36. The second resist layer 46 is preferred to have a greater etch resistance than the first resist layer 36, and therefore the portion of the first resist layer need to be removed can be removed easily. For example, the second resist layer can include hard mask material such as a polymer, Si, silicon oxide, an organic silicon polymer, polysilane, or a cross-linked material, etc., but it is not limited thereto. The method of forming the second resist layer may be, for example, a coating process or a deposition process. The coating process may be a dipping, spraying, or spin coating, etc. The deposition process may be a chemical vapor deposition (CVD) process or a physical vapor deposition (PVD) process, etc. When using polymer materials as the second resist layer 46, a curing process can be further performed after the second resist layer is formed.

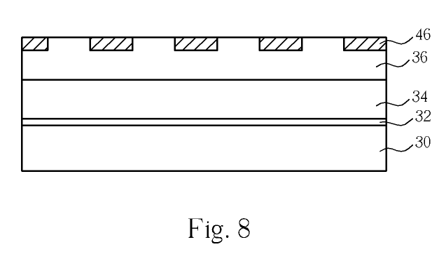

Then, as shown in FIG. 8, a portion of the second resist layer 46 is removed. The removal may be performed using a chemical mechanical polishing (CMP) process or an etching back process, and the etching back process may include a dry etch process or a wet etch process.

U.S. Pat. No. 6,025,117 discloses a method of forming a pattern by using polysilane, wherein the polysilane material as a mask and the removing method thereof can be a reference for the second resist layer and the partial removal thereof in the present invention, and therefore the U.S. Pat. No. 6,025,117 is hereby incorporated by reference.

After removing a portion of the second resist layer 46, the top surface of the second resist layer can be higher than the top surface of the first resist layer, or the top surface of the second resist layer can be coplanar with the top surface of the first resist layer, or the top surface of the second resist layer can be lower than the top surface of the first resist layer. There is no particular limit about the depth of the removing portion of the second resist layer, and therefore when the portion of the second resist layer is removed using a CMP process or an etching back process, there is enough operation tolerance and the process defects will not come up easily, and the process yield can be increased.

In the CMP process, the adhesion between each layer must be considered to avoid the lift-off defect due to friction. In the present invention, since the first resist layer has a certain thickness (not too thin) and covered with the second resist layer to be in a damascene-like structure, the lift-off defect does not come up during the CMP process.

According to the material properties of the second resist layer, a cross-link treatment can be performed on the second resist layer after or before the CMP process.

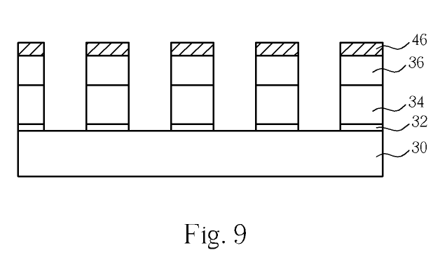

Finally, as shown in FIG. 9, the second resist layer is used as a hard mask to etch and remove the exposed portion of the first resist layer and the layer to be etched underlying the exposed portion of the first resist layer, i.e. the polysilicon layer 34 and the gate dielectric layer 32, to form the desired pattern. Finally, the second resist layer 46 and the first resist layer 36 can be further removed to remain the pattern of the layer to be etched on the substrate. In this embodiment, the pattern formed by the polysilicon layer and the gate dielectric layer is remained to form the gate structure. Therefore, the second resist layer is used as a hard mask to etch and remove the exposed portion of the first resist layer and the layer to be etched under the exposed portion of the first resist layer in the present invention, and since the hard mask pattern is formed via patterning the first resist layer, the hard mask pattern has an extremely good resolution. Besides, during etching and removing the exposed portion of the first resist layer and the layer to be etched under the exposed portion of the first resist layer, the hard mask has a relatively high etch resistance, and the underlying layer is protected from being damaged in the etch process. In addition, the first resist layer and the second resist layer have a certain thickness and good adhesion with the layer to be etched of the substrate, and therefore there is no lift-off problem. Thus, the fine pattern can be obtained at last.

Please note that after the portion of the second resist layer is removed using an etch process in the present invention, an etch process in the next step, i.e. the second resist layer is used as a hard mask to etch and remove the exposed portion of the first resist layer and the layer to be etched under the exposed portion of the first resist layer, may be performed in a way as follows: be performed in the same chamber, be performed by changing machines, or be performed by changing different chambers in the same machine. Therefore, it may be performed as desired for more convenience of the process.

As shown in FIG. 8, a portion of the second resist layer 46 is removed, and the first resist layer 36 is exposed. However, the case that, after removing the portion of the second resist layer 46, the first resist layer 36 is still covered by a thinner second resist layer 46 is also encompassed in the scope of the present invention. Since the second resist layer has a greater etch resistance than the first resist layer, the thinner second resist layer, and the first resist layer and the layer to be etched under the thinner second resist layer can be removed in sequence by etching to form the pattern.

Please note that the embodiments of the present invention can have several variations, such as:

patterning the top of the first resist layer using an imprint method, and, after forming a second resist layer on the patterned first resist layer, removing a portion of the second resist layer by CMP process; or

patterning the top of the first resist layer using an imprint method, and, after forming a second resist layer on the patterned first resist layer, removing a portion of the second resist layer by etching back process; or

patterning the top of the first resist layer using a litho-etch method, and, after forming a second resist layer on the patterned first resist layer, removing a portion of the second resist layer by a CMP process; or

patterning the top of the first resist layer using a litho-etch method, and, after forming a second resist layer on the patterned first resist layer, removing a portion of the second resist layer by etching back process; or

patterning the top of the first resist layer using an electron beam lithography method, and, after forming a second resist layer on the patterned first resist layer, removing a portion of the second resist layer by CMP process; or

patterning the top of the first resist layer using an electron beam lithography method, and, after forming a second resist layer on the patterned first resist layer, removing a portion of the second resist layer by etching back process.

The method of forming a pattern according to the present invention has the advantages as follows. First, the photoresist thickness can be controlled to be less than 300 angstroms after etching back process, and it depends on a gap filling process in the formation of the second resist layer on the patterned first resist layer. There are no adhesion problems. The gap filling process can be provided for the beol process of 90 nm and 65 nm. Second, since the polymer hard mask cheaper than the inorganic hard mask can be used, additional cleaning, deposition, and removing process are not required, and the hard mask is not required to be removed after the pattern is formed, the method is more economical. Third, conventionally there might be lift-off problems of the pattern when removing the portion of the resist layer by using a CMP process, but in the present invention, the lift-off problems may not occur due to the damascene-like structure.

All combinations and sub-combinations of the above-described features also belong to the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a pattern, comprising:
providing a substrate comprising a layer to be etched;
forming a first resist layer on the substrate;
patterning a top of the first resist layer;
forming a second resist layer on the patterned first resist layer;
removing a portion of the second resist layer; and
etching the second resist layer, the first resist layer, and the layer to be etched.

2. The method of claim 1, wherein, the second resist layer has a greater etch resistance than the first resist layer.

3. The method of claim 1, wherein, after removing a portion of the second resist layer, the top surface of the second resist layer is higher than the top surface of the first resist layer.

4. The method of claim 1, wherein, after removing a portion of the second resist layer, the top surface of the second resist layer is coplanar with the top surface of the first resist layer.

5. The method of claim 1, wherein, after removing a portion of the second resist layer, the top surface of the second resist layer is lower than the top surface of the first resist layer.

6. The method of claim 1, wherein, the first resist layer comprises a photoresist material.

7. The method of claim 1, wherein, the second resist layer comprises a hard mask material.

8. The method of claim 7, wherein, the hard mask material comprises a polymer, Si, silicon oxide, an organic silicon polymer, polysilane, or a cross-linked material.

9. The method of claim 1, wherein, patterning the top of the first resist layer is performed using an imprint method, a litho-etch method, or an electron beam lithography method.

10. The method of claim 1, wherein, forming a second resist layer on the first resist layer is performed using a coating or deposition method.

11. The method of claim 1, after forming the second resist layer, further comprising a curing process to cure the second resist layer.

12. The method of claim 1, wherein, removing a portion of the second resist layer is performed using a chemical mechanical polishing process or an etching back process.

13. The method of claim 12, wherein, removing a portion of the second resist layer is performed using a chemical mechanical polishing process and a cross-link treatment is further performed on the second resist layer after or before the chemical mechanical polishing process.

14. The method of claim 1, wherein, the first resist layer comprises a multilayer structure.

15. A method of forming a pattern, comprising:
providing a substrate comprising a layer to be etched;
forming a first resist layer on the substrate;
patterning a top of the first resist layer;
forming a second resist layer on the patterned first resist layer and covering the patterned first resist layer;
removing a portion of the second resist layer to expose a portion of the first resist layer; and
etching the exposed portion of the first resist layer and the layer to be etched under the exposed portion of the first resist layer.

16. The method of claim 15, wherein, the second resist layer has a greater etch resistance than the first resist layer.

17. The method of claim 15, wherein, after removing a portion of the second resist layer, the top surface of the second resist layer is higher than the top surface of the first resist layer.

18. The method of claim 15, wherein, after removing a portion of the second resist layer, the top surface of the second resist layer is coplanar with the top surface of the first resist layer.

19. The method of claim 15, wherein, after removing a portion of the second resist layer, the top surface of the second resist layer is lower than the top surface of the first resist layer.

20. The method of claim 15, wherein, the first resist layer comprises a photoresist material.

21. The method of claim 15, wherein, the second resist layer comprises a hard mask material.

22. The method of claim 21, wherein, the hard mask material comprises a polymer, Si, silicon oxide, an organic silicon polymer, polysilane, or a cross-linked material.

23. The method of claim 15, wherein, patterning the top of the first resist layer is performed using an imprint method, a litho-etch method, or an electron beam lithography method.

24. The method of claim 15, wherein, forming a second resist layer on the first resist layer is performed using a coating method or a deposition method.

25. The method of claim 15, after forming the second resist layer, further comprising performing a curing process to cure the second resist layer.

26. The method of claim 15, wherein, removing a portion of the second resist layer is performed using a chemical mechanical polishing process or an etching back process.

27. The method of claim 26, wherein, removing a portion of the second resist layer is performed using a chemical mechanical polishing process and a cross-link treatment is further performed on the second resist layer after or before the chemical mechanical polishing process.

28. The method of claim 15, wherein, the first resist layer comprises a multilayer structure.
